(19) United States
(12) Patent Application Publication
(10) Pub. No.: US 2026/0367012 A1
(43) Pub. Date: Nov. 19, 2026

(54) System and Method for Die Inspections

(71) Applicant: Semiconductor Technologies and Instruments Pte. Ltd., Singapore (SG)

(72) Inventors: Ajharali Amanullah, Singapore (SG); Hancheng Ge, Singapore (SG)

(21) Appl. No.: 19/514,977

(22) PCT Filed: Aug. 28, 2024
(86) PCT No.: PCT/SG2024/050553

§ 371 Date: Feb. 27, 2026

(30) Foreign Application Priority Data
Aug. 28, 2023 (WO) PCT/SG2023/050587

(51) Int. Cl. G01N 21/88; G01N 21/956

(52) U.S. Cl. CPC G01N 21/8806; G01N 21/95684; G01N 2021/8825

(57) ABSTRACT

Systems and methods for inspecting a surface of a workpiece are disclosed. The workpiece may be a packaged die, processed wafer or other types of workpieces. An adapted Michaelson setup is employed to produce fringe patterns from illuminating the surface with a long coherence length illumination, such as infrared (IR) illumination. The Michealson setup includes a first reflected illumination from a reference mirror and a second reflected illumination from the surface of the workpiece. The reflected illuminations are directed to an image capture module by a primary beam splitter. The reference mirror, the die surface and the primary beam splitter are configured to maintain a constant phase difference between the reflected illuminations to enable constructive interference to produce the fringe patterns. The Michelson setup enables the detection of submicron cracks, down to 0.2-0.25 um. The Michelson setup can be implemented into a standalone system or in an integrated system for detecting a range of defects, from micron-sized defects or greater down to submicron-sized defects (e.g., as small as 0.2-0.25 um).

### CROSS-REFERENCE TO RELATED APPLICATIONS

This application is the United States national phase of International Patent Application No. PCT/SG2024/050553 filed Aug. 28, 2024, and claims priority to International Patent Application No. PCT/SG2023/050587 filed Aug. 28, 2023, the disclosures of which are hereby incorporated by reference in their entireties.

### BACKGROUND

### Technical Field

This disclosure relates to a system and a method for inspecting dies and wafers. The system and method are capable of detecting defects, such as cracks on the surface of at least one die, including packaged die and dies with smooth or mirror surface finish as well as a surface of wafers. In particular, the system and method enable the detection of a full range of micron-sized surface defects down to submicron-sized cracks with minimal false positives and at high production speeds. The system and method are also able to distinguish between cracks and other surface irregularities like grinding lines which may not be defects.

### TECHNICAL CONSIDERATIONS

Many wire-bonded Integrated Circuit (IC) devices are typically encapsulated by injecting a molding compound around the die to prevent damage, corrosion, and oxidation to the wire bonding, resulting in an encapsulated package. After encapsulation, it may be desirable to have the back surface (opposite the active surface) of the die exposed. Exposing the back die surface is performed principally to improve heat dissipation of the package. To expose the die surface, low-profile grinding blades are used to reduce the thickness of the molding compound until the back inactive silicon surface of the embedded die is exposed. The grinding may cause grinding lines on the inactive die surface.

Even before the grinding process, package warpage may occur due to temperature changes. For example, the coefficient of expansion (COE) differences between the silicon die and the molding compound can cause warpage. Such warpage may cause cracks to appear on the embedded die. In addition, during the grinding process to expose the inactive die surface, temperature changes or even the pressure applied to the die during grinding may further cause additional cracks and fine grinding lines to appear.

Furthermore, package warpage can also cause the inactive die surface to suffer stress and crack. Cracks may also occur on the inactive die surface caused by warpage due to the assembly process. These cracks can be very thin (e.g., less than 0.25 μm in width) and are very difficult to detect with conventional inspection systems employing low-cost macro-objective/telecentric lenses and sensors.

Conventional package visual inspection (PVI) solutions may employ various types of lenses. For example, macro-objective lenses (general applications). For example, macro-objective and telecentric lenses typically have a resolution of about 2.5-4.6 um or greater. As such, they usually cannot detect submicron cracks or defects, such as grinding lines of about 0.2-1 um unless special inspection techniques are used (eg. the use of collimated light can enhance crack detection). However, even if conventional inspection systems with enhanced techniques can detect submicron cracks or other surface irregularities like grinding lines, it is usually beyond the resolution of the camera sensors of these conventional inspection systems to resolve and distinguish between the two. The presence of grinding lines or other surface irregularities complicates inspection, as they may not be defects and their detection results in many false positives.

The resolution of a lens clearly plays an important part in accurate defect detection. The inability to resolve a defect smaller than its resolution results in a lower defect contrast and negatively impacts inspection performance as described aforesaid.

The obvious solution would be to use micro-objective lenses, as their higher magnification can detect and possibly resolve submicron defects due to their higher resolution. However, the much higher magnification of the micro lenses comes with a higher cost. They also require correspondingly high camera sensor resolution, such as around 200-380 MP for defect resolution down to 0.2 μm. Such high-resolution camera sensors are significantly more costly than the camera sensors used with macro-objective or telecentric lens systems (4-25 MP).

Not only are micro-objective lens systems much more expensive than macro-objective or telecentric lens systems, but they are also incapable of meeting the needs of production applications. In particular, the consequences of the ultra-high magnification of micro-objective lenses come with a small field of view (FOV) and shallow depth of focus (DOF). Having a small FOV requires more images to be captured to inspect relatively larger packages. The relatively larger number of images necessary to image a complete die package also requires the application of algorithms as well as needing much more time to stitch the images together for use. Furthermore, the shallow DOF of micro-objective lenses makes the optical system much more vulnerable to vibrations inherent in operating semiconductor equipment. Due to the relatively shallow DOF, images acquired under high magnification during vibrations are often blurry making them unsuitable for defect inspection. As such, the lack of production performance of the high-cost high-resolution inspection systems using micro-objective lenses makes them impractical or unsuitable for production applications.

Encapsulated dies are not the only type of dies that requires inspection for cracks (including submicron cracks). Other types of dies with near mirror finish or mirror finish, like MEMS, LEDs, solar cells CMOS sensors, GaN devices, and silicon photonic devices. All these devices require a mirror finish to optimize light interaction, absorption, thermal management, electrical performance, and optical performance or minimize light loss or distortion. Such inspection may suffer equally from the deficiencies of conventional crack inspection systems.

Further, in the semiconductor industry, bare or plain wafers are used in semiconductor manufacturing. The plain wafer surface typically requires inspection before forming the silicon oxide layer. This initial inspection is crucial to detect any surface defects or imperfections that could affect the quality of the silicon oxide layer or subsequent device fabrication. Conventionally, this initial inspection step is often performed using various methods including visual inspection using high magnification microscopes, surface particle counters scanning electron microscopy (SEM) and atomic force microscopy (AFM). These inspection systems can range from $150,000 to $1 million or more.

Based on the foregoing discussion, there is a need for a new inspection solution that can accurately and reliably detect submicron cracks, such as about 0.2 to 1 μm which is cost-effective and practical for inspection of surfaces of dies or wafers with good throughput. The inspection solution in this disclosure may be applicable not just to inspect die surfaces for cracks, it may be applied to any surfaces that may require inspection for submicron cracks such as bare wafer surface or even the silicon dioxide layer after bare wafer inspection.

### SUMMARY

A solution for inspecting the inactive surface of a die package is disclosed. In one non-limiting embodiment, the solution includes an inspection system with an adapted Michelson setup for detecting cracks on a surface of the workpiece. The inspection system includes an illumination module configured to generate fringe patterns in the image of the surface of the workpiece illuminated. The illumination module includes an illumination source. The illumination source generates the illumination. The system also includes an optical module. The optical module includes an illumination collimator to collimate the illumination from the illumination source. The system also includes an image capture module to capture an image of the fringe patterns. The system further includes a detection module configured to analyze and detect changes to the fringe patterns caused by height and planarity differences in the surface along and adjacent to a crack to indicate the presence of a crack.

In another non-limiting embodiment, the solution includes an integrated inspection system for detecting surface irregularities on a surface of a workpiece. The system includes a Mode-1 inspection module configured to illuminate the surface of the workpiece on a planar platform. Illuminating the surface of the workpiece is with a co-axial diffused bright (BF) illumination or darkfield (DF) illuminations or a combination thereof to detect micron-sized surface irregularities on the surface of the workpiece. The surface irregularities include contaminates, cracks and grinding lines. A Mode-2 inspection module is configured to illuminate the surface of the workpiece on the planar platform with Mode-2 collimated BF illumination directed perpendicularly to the surface of the workpiece to detect micron-sized and submicron-sized surface irregularities. However, the Mode-2 inspection module is unable to resolve or distinguish whether sub-micron-sized surface irregularities are cracks or grinding lines. A Mode-3 inspection module is configured to illuminate the surface of the workpiece on the planar platform with Mode-3 IR illumination to produce regular fringe patterns from the surface of at least one die. Changes in the fringe patterns are indicative of height and planarity differences between the surface along and adjacent to a crack which are crack characteristic of a crack's presence, thereby enabling the detection of the submicron crack and differentiating submicron cracks from grinding lines that lack the crack characteristic.

In yet another non-limiting embodiment, the solution includes a method for inspection a surface of a workpiece. The method can distinguish between types of submicron-sized irregularities on the surface of the workpiece. The method includes performing a Mode-2 inspection by illuminating the surface of the workpiece with Mode-2 collimated BF illumination directed perpendicularly to the surface of the workpiece to obtain a Mode-2 image of the surface of the workpiece. Mode-2 image indicates possible micron-sized or greater and submicron-sized surface irregularities. The surface irregularities include, for example, contaminates, cracks and grinding lines. However, the Mode-2 inspection is unable to resolve or distinguish whether the submicron-sized surface irregularities are cracks or grinding lines. A Mode-3 inspection is performed by illuminating the surface of the workpiece with Mode-3 collimated IR illumination to produce regular fringe patterns from the surface of the workpiece and to obtain a Mode-3 image of the fringe patterns. The Mode-2 and Mode-3 images are analyzing, which includes identifying an area in the Mode-2 image which indicates a possible surface irregularity. The corresponding area in the Mode-3 image is analyzed to determine if there is a fringe pattern change. If the analysis indicates that there are fringe pattern changes in the area, then infer that the surface irregularity is a crack. On the other hand, if there are no fringe pattern changes in the area, then infer that the surface irregularity is not a crack.

In yet another non-limiting embodiment, the solution is directed to an integrated inspection system. The system includes a processing unit configured to perform comprehensive defect detection and classification across Mode-1, Mode-2, and Mode-3 inspection modes for inspecting a surface of a workpiece. The system also includes a buffer memory for efficiently handling and storing image data from the Mode-1, Mode-2, and Mode-3 inspection modes. The Mode-1 inspection mode of the system is configured to detect and classify defects from Mode-1 images obtained in the Mode-1 inspection mode. Classifying defects includes classifying contaminants, scratches, divots, and pits. Mode-1 classification information from Mode-1 inspection is stored in the buffer memory. The Mode-2 is configured to detect micron-sized cracks from Mode-2 images obtained in the Mode-2 inspection mode and identifies potential defects, including submicron cracks and grinding lines. Locations of potential defects on the surface of the workpiece are linked as defect regions of Interest (DROI). Mode-2 DROI information is stored in the buffer memory. The Mode-3 inspection mode is configured to retrieve the Mode-2 DROI information from the buffer memory and to capture high-resolution Mode-3 fringe pattern images. The Mode-3 images are analyzed to distinguish between actual defects and non-defects based on changes in fringe patterns to finalize defect classification.

These and other advantages and features of the embodiments herein disclosed will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of various non-limiting embodiments. In the following description, various non-limiting embodiments of the present disclosure are described with reference to the following, in which:

FIGS. 1a-1b show top and cross-sectional views illustrating the various defects and non-defects on a die surface;

FIG. 1c shows a magnified cross-sectional view of a portion of the die with a submicron crack;

FIGS. 2a-2b are schematic diagrams illustrating the features of non-limiting embodiments of a system for inspecting defects;

FIG. 3 is a schematic block diagram showing the features of the system for Mode-1 inspection of surface defects in accordance with a non-limiting embodiment of the disclosure;

FIG. 4 is a schematic block diagram showing the features of the system for Mode-2 inspection for die defects in accordance with a non-limiting embodiment of the disclosure;

FIG. 5 is a schematic block diagram showing the features of the system for Mode-3 inspection for submicron dies cracks in accordance with a non-limiting embodiment of the disclosure;

FIGS. 6a-6b show non-limiting embodiments of a standalone Mode-3 inspection system;

FIG. 7 is a flow diagram for analyzing defects to determine the presence of submicron cracks in accordance with non-limiting embodiments of the disclosure; and

FIGS. 8a-8c show exemplary images from Mode-3 inspection indicating no submicron cracks and the presence of submicron cracks.

### DETAILED DESCRIPTION

The disclosure provides a system and a method for accurate detection, confirmation and classification of a full range of defects such as scratches, divots, pits, contaminant and micron-sized surface defects down to submicron cracks and surface irregularities such as grinding lines for a workpiece, such as a die or a wafer.

The system and method may be applied to a variety of workpieces, such as dies and processed wafers or workpieces with a shiny surface which needs to be inspected. In the case of a die, it may include a packaged die which a molded compound has been ground to expose the inactive silicon surface to reduce its form factor and for heat dissipation. The warpage of molded compound and the grinding process may cause cracks to form. Cracks may propagate to the active layers of the die and hence require inspection. Other types of dies including various types of MEMS devices with its array of minute electro-mechanical mirrors in flat state may be inspected for contamination or cracks which may affect functional integrity or performance. Relatively low-cost die inspection systems with the ability to distinguish submicron cracks from grinding lines (which are not defects) will reduce significant false positives in defect detection while providing high throughput in production is one capability highly priced and sought after.

Bare or plain wafers are used in semiconductor manufacturing. A plain wafer may be referred to also as a blank wafer. Blank wafers have a shiny surface. The plain wafer surface typically requires inspection before forming the silicon oxide layer. This initial preparatory inspection is crucial to detect any surface defects or imperfections that could affect the quality and integrity of the silicon oxide layer or subsequent device fabrication. Defects to be inspected for include scratches, divots, pits, contaminants, crystal defects, and cracks including submicron cracks as a preparatory step before other processes follow. In a wafer preparation process, the silicon oxide layer typically doesn't require inspection for cracks, as it is a thin, conformal layer. However, inspection might be necessary in certain cases where in critical applications the silicon oxide layer serves as a critical component, such as a gate oxide or a dielectric layer, or where the thickened silicon oxide layer is relatively thick (e.g., for masking or insulation purposes), inspection for cracks or defects might be required to prevent issues during subsequent processing steps. Further, if the wafer has undergone significant stress or deformation during processing, inspection of the silicon oxide layer for cracks or defects might be necessary to ensure its integrity.

Furthermore, it will be apparent to a person skilled in the art that this disclosure does not preclude the present disclosure from other inspection applications where fundamental principles prevalent among the various non-limiting embodiments of the present disclosure such as operational, functional, or performance characteristics are required.

Although the drawings illustrate a non-limiting embodiment of the inspection system inspecting a single die, this depiction is merely exemplary and not limiting. As will be described below, the inspection system, its components or modules, and the inspection process itself are configurable to inspect one or multiple dies, or a portion/entire wafer, depending on the field of view (FOV). The scope of the disclosure should not be inferred to be limited to the specific example shown in the drawings. Further, unless otherwise specified, descriptions of the inspection process or setup, including its components or modules, explained with reference to die inspection are equally applicable to whole wafer inspection. Any differences between die and wafer inspection will be explicitly elaborated upon.

Throughout this disclosure, ‘surface’ refers to the specific surface of a die or wafer designated for defect inspection, applicable to various device types (bare dies, packaged dies with exposed silicon, MEMS, etc.), wafers (processed or blank wafers) as well as devices having a shiny surface. For inspection, this surface is assumed to be properly oriented, presented facing upwards on the planar platform, and ready for inspection. In the case of whole wafers or dies on film frame, it is assumed that proper alignment and orientation checks have been performed, the wafer or film frame is securely placed on the wafer chuck and registered against alignment pins, and the surface requiring inspection faces upwards. Unless otherwise specified, ‘presenting for inspection’ implies presenting this designated surface. For clarity and not to obscure the main concepts of the disclosure, this disclosure omits detailed descriptions of familiar techniques and configurations, including presenting dies in trays or bare silicon/silicon oxide layered on a wafer chuck against reference markers, and mechanisms for moving the wafer to enable scanning the entire surface. These conventional details are assumed to be familiar to those skilled in the art.

In this disclosure, ‘detectable but not resolvable’ refers to a defect that can be detected by the inspection system, but whose dimensions or characteristics cannot be accurately determined because its size is smaller than the system's resolution. For example, a submicron crack measuring 0.2 microns in width may be detected by a system with a pixel resolution of 4.6 microns, but its true size and shape will not be accurately represented in the image, instead appearing at least as a pixel-sized feature (e.g., 4.6 microns) due to the system's inability to resolve features smaller than its resolution limit.

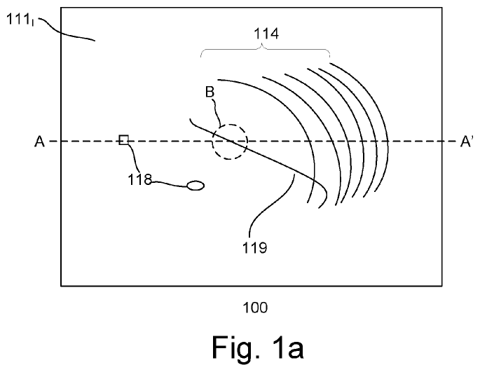

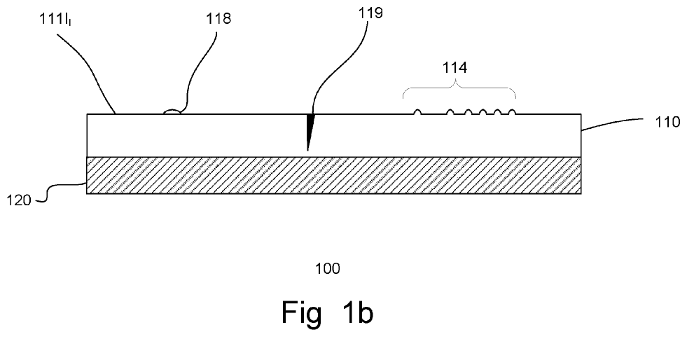

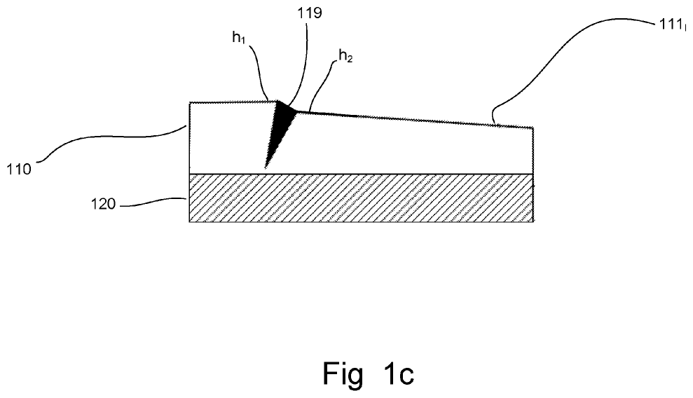

FIGS. 1a-1b illustrate an exemplary die 100 under inspection, showcasing surface irregularities like cracks, grinding lines, and contaminants, which can be micron-sized or submicron-sized. The drawings depict a molded die package 100 with the active layer 120 facing down and the molded compound (not shown) ground down to expose the inactive back surface 1111 of a substrate 110. The exposed die surface may feature surface imperfections or irregularities like grinding lines 114, cracks 119, and contaminants 118. The dark color represents the crack line.

FIG. 1c presents a magnified cross-sectional view of the die surface (the portion of FIG. 1a along the A-A′ line indicated as B), revealing a crack 119 caused by stress from warpage of the molding compound. However, the characteristic feature of cracks-non-uniform topology on adjacent side surfaces along the crack line, with height differences and variations in angular orientation (planarity)—is not unique to warpage-induced cracks. This distinguishing feature is common to all stress-induced cracks, which tend to propagate along crystal lattices and may extend deeper into the die, potentially reaching active areas. Therefore, accurate detection and classification of cracks as defects are crucial.

Notably, Mode-3 inspection leverages this characteristic feature to differentiate cracks from grinding lines and other surface irregularities. By using fringe patterns to detect the unique height and planarity variations along the crack line, Mode-3 inspection can reliably identify and classify cracks, ensuring accurate defect detection and classification.

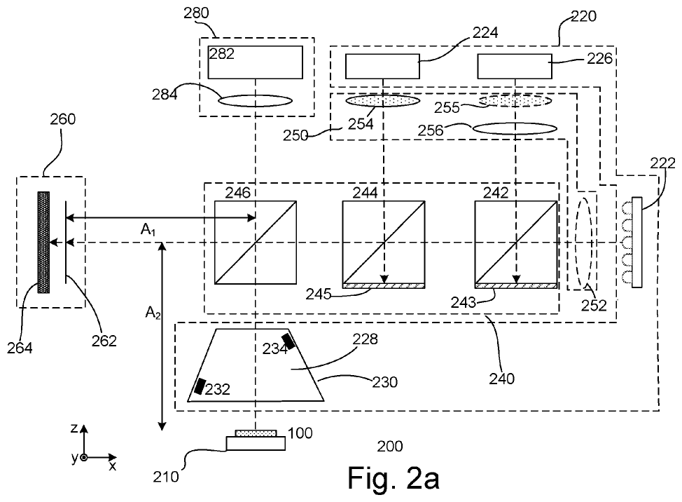

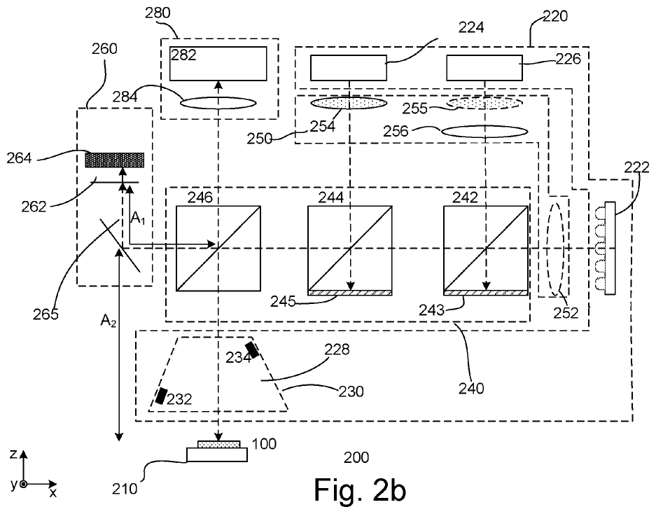

FIG. 2a illustrates a non-limiting embodiment of an inspection system 200. In one non-limiting embodiment, the inspection system 200 is an integrated inspection system. The integrated inspection system integrates or includes 3 inspection modules working in 3 different modes, namely, Mode-1 Diffused Brightfield/Darkfield Inspection Module (hereinafter “Mode-1 module” or “Mode-1”); Mode-2 Collimated BF Inspection Module (hereinafter “Mode-2 module” or “Mode-2”); and Mode-3 Fringe Pattern Module (hereinafter “Mode-3 module”) or “Mode-3”).

### Mode-1

In one non-limiting embodiment, the main components for Mode-1 inspection include the brightfield (BF) illumination unit 222 and darkfield (DF) illumination unit 228, a beam splitter 246 and a common image capture module 280 (including a telecentric lens 284 and a camera 282) and a planar platform 210. As shown, the BF illumination unit includes a BF illuminator and the DF illumination unit includes DF illuminators, such as angled DF illuminators 232 and 234. It is understood that beam splitters 242 and 244 of a beam splitter assembly module 240 and the reference module 260 are not necessary components of Mode-1 inspection if the systems were configured as a standalone Mode-1 inspection system. As part of the inspection system 200, their interaction with Mode-1 components will be described.

### Mode-1 Illumination

In one non-limiting embodiment, the Mode-1 inspection utilizes a combination of coaxial diffused broadband BF and DF illuminations to detect surface irregularities, such as contaminants, scratches, pits, divots as well as other micron-sized or greater surface irregularities. In one non-limiting embodiment, the Mode-1 illumination module includes a BF illumination unit 222 and a DF illumination unit 228.

### Mode-1 BF Illumination Unit

In one non-limiting embodiment, the BF illumination unit 222 includes a BF illuminator which generates co-axial diffused broadband illumination (visible or white light) with a wavelength bandwidth between 380-700 nm. The BF illuminator may include a flash lamp array, white light-emitting diode (LED) array, or other suitable light sources. In an alternative non-limiting embodiment, a single flash lamp or LED may be employed, and a BF expander lens 252 of the lens module 250 may be used to expand the point source illumination to a broad front co-axial diffused illumination. The BF illuminator can operate in either continuous or pulse (intermittent) mode.

### Mode-1 Darkfield (DF) Illumination Unit

In Mode-1, the DF illumination unit 228 includes multiple DF illuminators, in non-limiting embodiments, RGB LEDs, generating broadband DF illuminations with wavelengths between 380-700 nm, below the near-infrared range (<720 nm). The DF illumination unit 228, as shown in FIG. 2a is disposed between the inspection platform module 210 and the beam splitter 246 of the beam splitter assembly module 240. The DF illumination unit is configured to direct DF illumination(s) to the surface of the die on the inspection platform directly. In addition, the DF illumination unit is configured so as not to hinder illuminations from other illumination units, such as the first, second, and third illumination units 222, 224, and 226 to pass through (unhindered) to the die on the inspection platform when Mode-1 is not in operation.

As shown in FIG. 2a, the DF illumination unit includes a DF illuminator 228 and may include a first DF illuminator 232 and a second DF illuminator 234. In one non-limiting embodiment, the DF illumination unit 228 implemented includes an open-top and bottom trapezoidal dome with the inside surface thereof lined with rings and rings of RGB LEDs from top to bottom. The open top and bottom of the dome allow for illumination to pass through to the die 100. The inside surface of the dome is divided into segments/bands and any number of bands of LEDs may be selected to provide such number of low-angled DF illumination (LA-DF) or high-angled DF illumination HA-DF, either alone or in combination thereof, from any desired direction within the dome as may be required. Where the DF illumination unit implemented is a dome, as described aforesaid, DF illuminator 232 and DF illuminator 234 merely represent the selection of bands of LEDs to provide the LA-DF or HA-DF illumination that is selected for inspection. The band or bands selected determine the angle or angles used for the LA-DF or HA-DF illumination required. Other implementations may include providing separate motorized DF illuminators 232 and 234 that can be moved to provide DF illumination at low or high angles, as desired. Whatever the implementation, the angle, wavelength, and intensity of the illuminations of the DF illuminators are configurable and selectable depending on the inspection requirements. The DF illuminators are configurable to work in pulse or continuous mode.

It is apparent to those ordinarily skilled in the art that components used in Mode-1 inspection (Mode-1 module) are optimized to inspect for the presence of foreign contaminants, pits and divots, and other micron-sized or greater defects. However, the use of diffused illumination in Mode-1 inspection makes it challenging to detect cracks because it washes out the subtle surface features and defects, including fine cracks or grinding lines. The diffused light scatters in multiple directions, creating a uniform brightness that obscures the faint shadows and contrast changes indicative of cracks. As a result, cracks may remain undetected or appear less pronounced, reducing the effectiveness of Mode-1 inspection for crack detection.

### Mode-2 Inspection

In one non-limiting embodiment, Mode-2 inspection utilizes collimated broadband BF illumination to enhance the detection of cracks and surface irregularities, including submicron cracks and grinding lines. Submicron cracks may be classified as defects while grinding lines are not. The collimated illumination improves crack detection by reducing scattered light and increasing contrast, allowing for more accurate identification of crack defects.

In one non-limiting embodiment, the Mode-2 BF illumination module includes a Mode-2 BF illumination unit 224, a Mode-2 collimator lens or collimator 254, and beam splitters 244 and 246. The collimator 254 ensures that the light rays emitted by the Mode-2 BF illuminator are parallel to one another when reflected toward the surface of the die 100, thereby reducing angular scatter and increasing the signal-to-noise ratio. This results in a higher contrast image, enabling more effective detection of small cracks and surface irregularities.

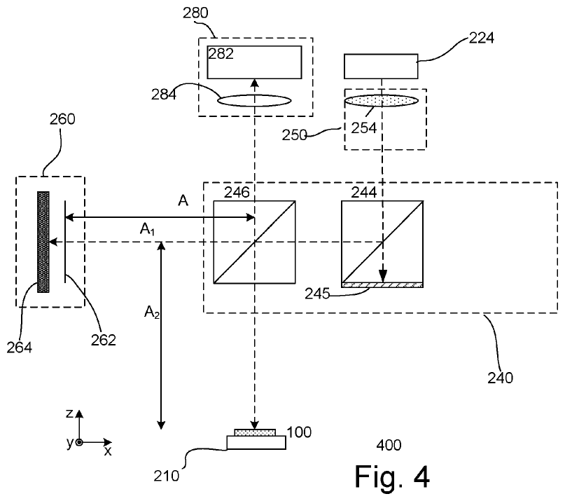

FIG. 4 illustrates one non-limiting embodiment of a Mode-2 inspection module of the system when operating in Mode-2. In this embodiment, the Mode-2 inspection module includes the Mode-2 BF illumination unit 224 with the BF illuminator and BF collimator 256 of the optical module 250, beam splitters 244 and 246 of the beam splitter assembly module 240 and the image capture module 280.

In one non-limiting embodiment, during Mode-2 operation, the Mode-1 BF and Mode-1 DF illumination units 222 and 228 as well as the Mode-3 illumination unit 226 are inactive. The Mode-2 BF illumination unit 224 with the Mode-2 BF illuminator may be a flash lamp or an LED. The Mode-2 BF illuminator is configurable to generate BF illumination having a broadband wavelength bandwidth of 380 to 700 nm, always less than the wavelength of IR illumination. The BF illuminator may operate in a continuous mode or a pulse mode, and its intensity may be controlled based on inspection requirements.

In one non-limiting embodiment, using conventional configurations for Mode-2 setups (refer to Table A for exemplary configurations), Mode-2 may be able to resolve micron-sized cracks having widths of 2 to 6 microns but may not be able to discern whether submicron-sized defects are cracks or grinding lines.

In one non-limiting embodiment, Mode-3 inspection uses an adapted Michelson setup that uses a long coherence length collimated infrared (IR) illumination to produce fringe patterns in images of the planar surface of the workpiece, such as a die/dice or wafer, being inspected. It is a novel application to a new field of use die/wafer surface inspection for cracks including submicron cracks. If there is one or more cracks, the regular fringe pattern would be broken by one or more starkly different fringe patterns. These stark fringe pattern changes are caused by the difference in planarity and heights between adjacent surfaces along the crack line that in turn causes relative phase differences in the IR illumination reflected by the reference mirror 262 and from the surface inspected which interference gives rise to changes in fringe patterns which is captured at the image capture sensor 282.

The use of fringe pattern analysis also gives Mode-3 inspection the capability to differentiate between cracks and grinding lines. For example, Mode-3 captures a fringe image of the surface of the workpiece already inspected by Mode-2. A Mode-2 image is used to indicate DROI(s) and corresponding DROI(s) on the Mode-3 image are analyzed for stark changes in fringe patterns, indicating a crack or cracks.

It is important to note that during the operation of Mode-1, Mode-2 and Mode-3 illuminators are not operational. That is to say, the collimated BF Illumination from the Mode-224 and collimated IR illuminator 226 are not in operation. At any one time, only illumination from one mode will be activated for that mode of operation. This ensures that there is no optical noise will be introduced by other illuminations in the other modes during the operations of any one mode. Additional details on Mode-3 will be provided in subsequent sections, where the operations of the different modes will be explained in further detail.

In one non-limiting embodiment, Mode-1, Mode-2 and Mode-3 inspection modules of the inspection system 200 interact with common components of the system. For example, the common components with which the different inspection modules interact may include the image capture module 280, beam splitter assembly module 240, reference module 260, and the planar platform 210.

### Description of the Planar Platform

In one non-limiting embodiment of the integrated inspection system 200, the planar platform 210 for holding a workpiece in position for inspection. In one non-limiting embodiment, the planar platform could be a mechanism to hold a tray with pockets, each pocket holding a die properly for inspection. In another non-limiting embodiment, the planar platform 210 may represent a wafer chuck holding down a plain wafer or a grounded or polished layer of silicon oxide on a wafer, properly registered against alignment pins for inspection of its surface. In one particular non-limiting embodiment, MEMS in wafer form is presented for inspection at the wafer chuck (planar platform). In one other non-limiting embodiment, singulated dies may be MEMS or other devices with smooth or mirror-finished surfaces on a film frame presented for inspection. In another non-limiting embodiment, the planar platform may be a film chuck holding down a film frame holding many dies for inspection. The wafer/film chuck is configured to move and position one or more dies on the wafer/film frame within the FOV of the inspection system for inspection. The exemplary “die” 100 in the drawing may represent one or more dies or a wafer presented on the planar platform for inspection. Other types of workpieces can also be supported by the planar platform for inspection.

### Description of the Image Capture Module

The image capture module 280 is a common module to all three modes of operation of the integrated inspection system 200. In one non-limiting embodiment, the image capture module includes an image capture unit 282 (image sensor unit) and a telecentric lens 284. The image capture unit, for example, may be an image sensor, such as a camera. The image sensor may be a CMOS sensor or a CCD sensor. Other types of sensors may also be useful.

As for the telecentric lens 284, it has a predetermined magnification based on any configuration that may be desired for defect inspection. In one non-limiting embodiment, the telecentric lens provides a large field of view (FOV) and distortion-free imaging with minimal vignetting. The telecentric lens is configured to capture and transform the reflected illumination from the surface of the workpieces, such as a die or a wafer (whether under Mode-1, Mode-2 or Mode-3) such that they will incident perpendicular or substantially perpendicular on the image sensor so that better contrast in the image can be achieved. The use of telecentric lens 284 ensures that the magnification of the die/s under inspection does not change across the field of view. This facilitates dimensional inspections as required. The use of collimated illumination in Mode-2 together with a telecentric lens greatly enhances image contrast in images captured for crack detection. Similarly, the collimated IR illumination in Mode-3 used in conjunction with the telecentric lens, enables good production of fringe patterns and higher contrast in the images for fringe analysis.

### Description of Collimators

Collimators 256 and 254 are used in Mode-2 and Mode-3 inspection, to enhance the quality of the image captured, in particular, by improving the contrast of the image captured. Collimated illumination where light rays are parallel to one another when directed perpendicularly to the die surface, enhances the ability of Mode-2 inspection system to detect fine cracks. The use of only collimated light to incident on a die surface for crack detection will yield better contrast of the crack than if inspected with diffused lighting as in Mode-1.

### Reference Module and the Beam Splitters Assembly

Mode-1 illuminators 222 and 228 and Mode-2 illuminator 224 are configured to operate within a wavelength bandwidth between 380-700 nm while Mode-3 illuminator 226 is configured to provide collimated IR illumination at any one wavelength between a band between 750-1000 nm. Providing IR illumination at 750-950 nm may also be useful. Other wavelengths may also be useful, depending on the surface being inspected. Mode-1 illuminator 222 is configured to provide broadband co-axial diffused BF illumination and DF illuminator 228 is configured to provide broad HA-DF or LA-DF diffused illumination either alone or in combination with co-axial diffused BF illumination from illuminator 222 as described earlier. Mode-2 illuminator 224 is configured to provide collimated BF illumination. The illuminators 222, 224, and 226 from Mode-1, Mode-2, or Mode-3, respectively, will be directed by the beam splitters of the beam splitter assembly module 240 to the surface of the die/dice/wafer during their operations. DF illuminator 228 when activated will provide diffused DF illumination at LA-DF or HA-DF illumination (as selectable as explained in earlier sections) directly to the die surface without interaction with the beam splitter assembly module 240.

Description of Beam Splitter Assembly—how it Interacts with the Illuminations of the Different Inspection Modes

This section will explain the interaction of illumination from each of the 3 modes with the reference module 260 and beam splitter assembly module 240. It should be noted that at any one time, only illumination from one inspection mode (Mode-1, Mode-2 or Mode-3) would be in operation. In one non-limiting embodiment, the beam splitter assembly includes beam splitters 242, 244, and 246. Beam splitter 246 may be referred to as a primary beam splitter. As shown in FIG. 2a, the beam splitters 242, 244, and 246 are arranged such that the center coincides with the central axis of the illumination unit 222 and the center of the reference mirror. At the same time, the center of beam splitter 242 is aligned with the central axis of the lens assembly 255 and collimator 256 (Mode-2 collimator), and beam splitter 244 is arranged such that its center aligns with the central axis of collimator 254 (Mode-3 collimator) and illuminator 226, while the center of primary beam splitter 246 is aligned with the central axis of the telecentric lens 284 and the center of the die 100. As shown, the primary beam splitter splits illumination from beam splitter 224 into first and second illumination paths, the first to the reference mirror and the second to the surface of the workpiece. As shown, the beam splitter assembly module 240, is configured to direct the illuminations to the planar platform to illuminate the die/dice or wafer during the operations of each mode of inspection and to the reference module 260.

Description of the Reference Mirror and how it Interacts with the Illuminations of the Different Inspection Modes.

In one non-limiting embodiment, the reference mirror 262, is a dichroic mirror. It is a requisite component of Mode-3 inspection but not required for Mode-1 or 2. The reference mirror is there because Mode-3 is integrated as part of the inspection system 200. In one non-limiting embodiment, the reference module includes the dichroic mirror 262 and light-absorbent material 264. The dichroic reference mirror 262 is coated with a suitable dielectric or metallic material (e.g., silicon dioxide, titanium dioxide or zirconium oxide, aluminum, silver, or gold) configured to selectively allow the transmission of Mode-1 and Mode-2 illuminations with a wavelength band of 380 nm to 700 nm from beam splitter 246. Illuminations from Mode-1 and Mode-2 operations passing through the dichroic reference mirror are absorbed by light-absorbent material 264. Mode-3 illumination, on the other hand, with near IR wavelength greater than 750 nm but less than 1000 nm or 950 nm is reflected by the dichroic mirror of the reference module. The reference mirror is configured with a highly reflective surface for IR illumination for Mode-3 with minimal aberrations.

Hence co-axial diffused BF illumination from illumination unit 222 (one of the Mode-1 illuminators) or collimated BF illumination from illumination unit 224 (Mode-2 Illuminator), both with an operating wavelength of 380-700 nm transmitted through beam splitter 246 when received by reference mirror 262 will be passed through and be absorbed by the light absorbent material 264. This arrangement ensures that no Mode-1 or Mode-2 illumination will be reflected from the reference mirror 262 and be received by beam splitter 246 during their respective operations. Otherwise, illumination reflected by reference mirror 262 and received by the beam splitter 246 will interfere with light reflected from the die toward the camera resulting in poor quality blurry and fringy images that cannot be used for purposes of Mode-1 and Mode-2 defect inspection. The reflected illumination of Mode-1 and Mode-2 at beam splitter 246, directed toward the die/wafer surface, will be reflected to the beam splitter 246 to image capture sensor 282. The reflection illumination to beam splitter 244 is inconsequential.

In one non-limiting embodiment, beam splitter 242 is configured as a dichroic mirror with a special coating that enables it to reflect substantially all IR illumination from IR illuminator 226 (with a wavelength above 750 nm but below 1000 nm) when Mode-3 is in operation while allowing BF illumination from 222 with wavelength bandwidth 380-700 nm to pass through when Mode-1 is in operation. With the coating, almost 100% of IR radiation from the IR illuminator 226 is reflected by beam splitter 242 to the second beam splitter 244 when Mode-3 is in operation. Any IR illumination that manages to pass through beam splitter 242 will be absorbed by light-absorbent materials 243.

Beam splitters 244 and 246 are 50/50 beam splitters, i.e., 50% are transmitted through and 50% reflected. IR illumination reflected from beam splitter 242 will be split 50/50 each time as it passes through beam splitters 244 and 246. The IR illumination reflected down at beam splitter 244 (Mode-3 beam splitter) will be absorbed by light-absorbent material 245. The light-absorbent material prevents unwanted illumination reflected within the internal surface from creating noise in the image captured. The IR illumination transmitted through beam splitter 244 (Mode-2 beam splitter) will be split at beam splitter 246 (primary beam splitter). Half of the IR illumination will be reflected downwards, while the other half will be transmitted to reference mirror 262. The IR illumination reflected at the surface of die 100 and reference mirror 262 will again be split when it reaches beam splitter 246. One-half of each will travel toward beam splitter 244 (50% of reflected IR illumination from the reference mirror is transmitted through and 50% of reflected IR illumination from the die surface will be reflected) but this has no consequence as they will be reflected away, and Mode-2 and Mode-1 are not in operation anyway. The other half of the reflected illumination from the reference mirror is reflected at beam splitter 246 toward the image capture module 280 and will interfere with the other half of the IR illumination reflected by the die and transmitted toward the image capture module 280. The interference of these two illuminations, depending on whether there is one or more cracks present that may cause relative phase differences in the interfering illumination, regular fringe patterns may be formed or a number of starkly different fringe patterns may be observed in the image of the die surface captured.

As described, beam splitter 244 may be referred to as the Mode-2 beam splitter. For example, the Mode-2 beam splitter's primary purpose is to reflect the Mode-2 illumination to the primary beam splitter 246 in the integrated inspection system. If Mode-2 inspection was a standalone system, only the primary beam splitter is needed. Regarding beam splitter 242, it may be referred to as the Mode-3 beam splitter because its main purpose is to reflect Mode-3 illumination to the primary beam splitter. As for the primary beam splitter 246, its main purpose is to split illuminations of the different Modes to the surface of the workpiece and to the reference module. For example, a first illumination path is directed to the reference module while a second illumination path is directed to the surface of the workpiece.

### Mode-3 Inspection: Enhanced Capabilities

In addition to detecting cracks, Mode-3 inspection's fringe pattern analysis can also identify other defects, including:
Stress-induced surface deformations caused by subsurface defects, such as subterranean cracks below the surface of a die; and
Pits or divots, which exhibit characteristic changes to regular fringe patterns.

By analyzing the fringe pattern changes, Mode-3 inspection can infer the presence of these defects, enabling a more comprehensive assessment of the surface of the workpiece, such as the die or wafer surface.

### Subterranean Crack Detection

The fringe pattern analysis can detect subtle deformations on the silicon surface caused by significant stress from subsurface defects, such as subterranean cracks. This requires high-sensitivity interferometry to detect the altered reflected light path and affected fringe pattern.

### Multi-Defect Detection

Mode-3 inspection's fringe pattern analysis can potentially be used to identify various defects, including cracks, subterranean cracks, pits, and divots on the die or wafer surface. Each defect type may exhibit characteristic changes to the regular fringe patterns, allowing for accurate identification and classification.

### Mode-3 as a Standalone System

It is also possible to use Mode-3 inspection system as a standalone to detect submicron cracks on dies or for in-line control inspection of wafer surface including the dielectric layer thereon before redistribution layer (RDL) processes. RDL processes refer to the processes of building layered metal interconnects that redistribute the input/output (I/O) connections to the semiconductor device on the wafer. In most dies today, multiple layers of RDL are needed before a new RDL layer is built. A layer of dielectric is used to insulate each RDL layer from the next, and vias are then etched to ensure proper connection between the RDL layers. Before vias are etched, to ensure a smooth surface for subsequent processing steps, the dielectric layer is often planarized using chemical-mechanical polishing (CMP). Each of these dielectric insulating layers would need to be inspected for defects including cracks before the next process steps.

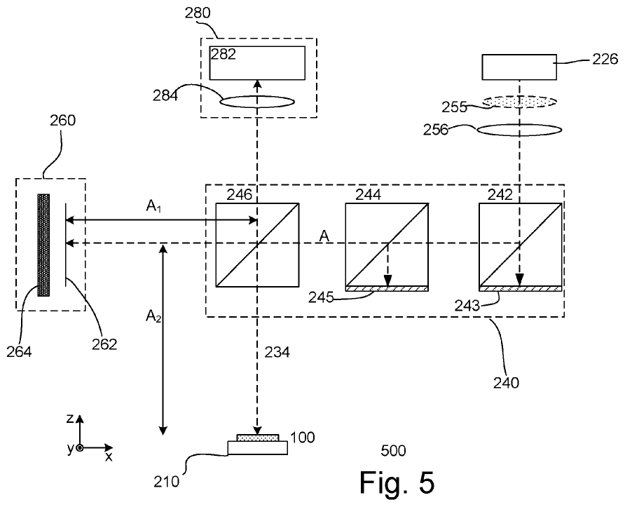

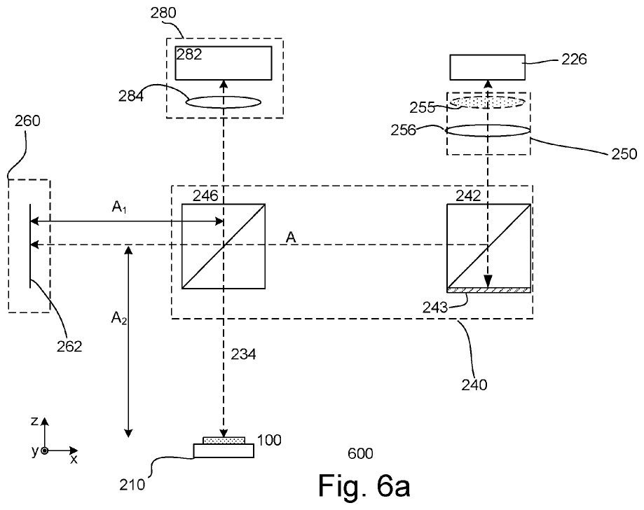

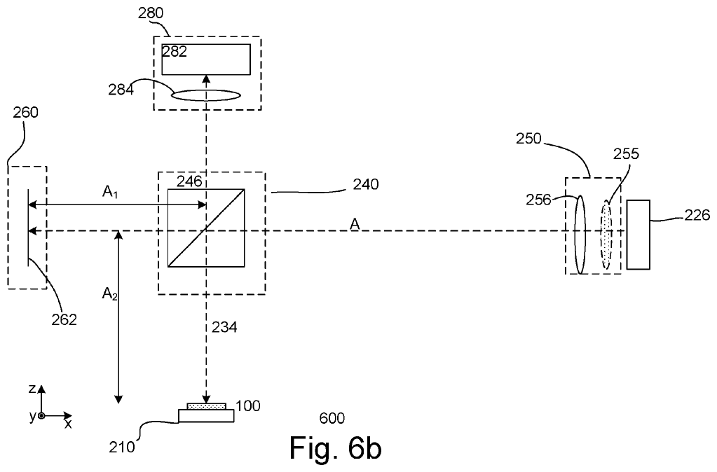

FIG. 6a shows a non-limiting embodiment of a Mode-3 standalone system 600 to produce fringe patterns for analysis and detection of the crack. The system is similar to Mode-3 components used in the system, as shown in FIG. 5. Common elements may not be described or described in detail.

The difference between the standalone system 600 and the Mode-3 components of FIG. 5 is that components exclusively used for Mode-1 and Mode-2 are eliminated or absent. For example, as shown in FIG. 6a, the beam splitter disposed between beam splitters 242 and 246 is eliminated. In addition, Mode-1 and Mode-2 illumination units and associated components of the lens module are eliminated. With respect to the reference module 260, the reference mirror 262 does not require any special coating to reflect light of only IR wavelength (within a narrow bandwidth) and to allow light of wavelength 380-700 nm to pass through to facilitate the integration of Mode-1 and Mode-2 operations. In one non-limiting embodiment, the reference mirror is configured to be a highly reflective reference mirror with minimal aberrations. Also, no absorbent material needs to be provided.

Furthermore, as a standalone, Mode-3 has a greater range on the choice of wavelengths to use, from lower UV to near-infrared below threshold wavelength that would increase absorption of IR light in the silicon material and eventually make it transparent to the IR illumination. The specific choice of wavelength to use will depend on the reflectivity of the surface, the material property of the surface, and the size of cracks to be detected. The wavelength should be chosen to optimize reflectivity, ensuring sufficient light returns to the detector to form fringe patterns. Shorter wavelengths (e.g., blue or violet light) are better suited for detecting smaller cracks, while longer wavelengths (e.g., red or infrared light) are more suitable for larger cracks. Certain materials may absorb or transmit specific wavelengths, affecting the choice of wavelength to be used; as in the case of silicon. In one non-limiting embodiment, the illumination unit 226 includes an LED coupled with a configurable wavelength filter. The illumination unit can be configured to generate illumination having a wavelength of 400-1000 nm. Generating illumination having other wavelengths may also be useful.

FIG. 6b shows another non-limiting embodiment of a Mode-3 standalone inspection system 600. The Mode-3 standalone inspection system is similar to the system of FIG. 6a. Common elements may not be described or described in detail. As shown, the standalone system has the Mode-3 illumination unit 226 and associated lens components (Mode-3 collimator 255 and Mode-3 lens illumination shaper lens assembly 256) repositioned so it is co-axially aligned with the center of beam splitter 246. For example, the Mode-3 illumination unit and associated lens components are repositioned so it is directly aligned with the center of the beam splitter 246. This avoids the need of another beam splitter, such as beam splitter 242 of FIG. 6a. Operationally, Mode-3 as a standalone works on the same principles as when it is part of the integrated inspection system 200 to detect cracks.

TABLE A

| Fixed | | | | | | | |
|---|---|---|---|---|---|---|---|
| by Pro- | Camera | | | | | | |
| ducer | Sensor | 25 MP | 25 MP | 25 MP | 12 MP | 4 MP | 4 MP |
| Fixed | Number | 5120 × | 5120 × | 5120 × | 4096 × | 2048 × | 2048 × |
| by pro- | of Pixel | 5120 | 5120 | 5120 | 3072 | 2048 | 2048 |
| ducer | Array | | | | | | |
| Fixed | Pixel | 4.5 | 4.5 | 4.5 | 5.5 | 5.5 | 5.5 |
| by pro- | Size | | | | | | |
| ducer | (μm) | | | | | | |
| Config- | FOV | 23 × 23 | 11.5 × | 5 × 5 | 6 × 6 | 2 × 2 | 11.2 × |
| urable | Size | | 11.5 | | | | 11.2 |
| | (mm) | | | | | | |
| | FOV | 23 k | 11.5 k | 5 k | 6 k | 2 k | 2 k |
| | Size | | | | | | |
| | (μm) | | | | | | |
| Config- | Magnif- | 1× | 2× | 5× | 1× | 5× | 1× |
| urable | ication | | | | | | |
| | of tele- | | | | | | |
| | centric | | | | | | |
| | lens | | | | | | |
| Config- | Resolu- | 4.49 | 2.24 | 0.98 | 1.46 | 0.98 | 5.5 |
| urable | tion of | | | | | | |
| | In- | | | | | | |
| | spection | | | | | | |
| | System | | | | | | |
| | (μm/ | | | | | | |
| | pixel) | | | | | | |

The number of dies that may be inspected in one image capture depends on the FOV of the inspection system which is configurable considering the die size. One or more dies can be inspected at one image capture so long as they can fit properly well within the FOV of the system.

The FOV, magnification and resolution of an inspection system can be configured by one ordinarily skilled in the art. Table A above exemplarily illustrates the relatively cost-effective setup of conventional inspection systems that this disclosure refers to that can still permit the detection and differentiation of submicron cracks and grinding lines. It shows some possible combinations of relatively cost telecentric lenses and image sensors for the inspection system 200 (than if microlenses and large MP sensors) that may be used for the inspection system. The resolution of the resultant inspection system determines the size of defects that can be resolved (as opposed to detection) at Mode-2. The combination of lenses and image sensors to be used depends on the requirements of the inspection and customers' demands. Even based on such configurations, it is possible to inspect more than one die at a time for all three modes of operations of this inspection system disclosed. Generally, the larger the FOV configured, the more dies can be inspected at once. Conversely, smaller FOVs require more passes or scans to inspect the same number of dies. The larger the magnification used, the smaller the FOV will shrink correspondingly for a given pixel size of the sensor. Additionally, the system's configuration, such as the magnification, resolution, and sensor size, can also impact the number of dies that can be inspected.

Inter-related factors to consider include how big the FOV should be. This will, in turn, depend on the size of the die to be inspected and how many dies are desired to be inspected in one go. What the defect resolution of the inspection system at Mode-1 and Mode-2 should have depended on the level of defect resolution required by the customer for Mode-1 or Mode-2 considering throughput and costs.

Whatever the image resolution for Mode-1 and Mode-2 that is configured, the combination would work so long as the image resolution is not worse than 5-7 μm. Mode-2 will still be able to detect submicron cracks or grinding lines except that it cannot distinguish between the two. Mode-3 gives the inspection system the capability to distinguish between grinding lines and submicron cracks. Mode-3 can detect the presence of micron-sized irregularities, including submicron cracks down to 0.2-0.25 μm. The sensitivity of Mode-3 which is based on fringe analysis (which will be explained in greater detail in later section) is determined by the wavelength of light used.

### Mode-1 Inspection

In one non-limiting embodiment, the main components for Mode-1 inspection include the BF illumination unit 222 and DF illumination unit 228, beam splitter 246, and the common image capture system 280 (telecentric lens 284 and camera 282), and planar platform 210. The beam splitters 242 and 244 and the reference modules are not necessary components of Mode-1 module if were a standalone system. As part of the integrated inspection system 200, interaction with Mode-1 components will be described.

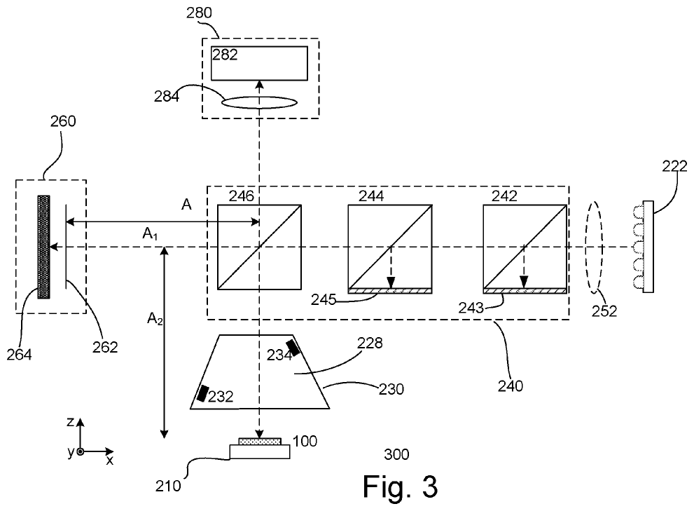

FIG. 3 illustrates a non-limiting embodiment of a Mode-1 module 300 as integrated into the inspection system of FIG. 2a. Components of the system not used in Mode-1 are not shown to improve understanding of its operations. For example, only the Mode-1 BF broadband illumination unit 222, DF illumination unit 228 and other components along the illumination path to the die 100 and reflected therefrom to the image capture module 280 are shown. How the illumination is conveyed has been explained in earlier sections and will not be repeated here.

As described, Mode-1 inspection in one non-limiting embodiment utilizing macro-objective lenses and lower resolution cameras as set out in Table 1, is typically capable of only detecting micron-sized or larger contaminants, scratches or other irregularities on the surface of the die. Because Mode-1 uses diffused co-axial illumination, fine grinding lines or submicron cracks may not show up as clearly in the images captured. To detect the presence of grinding lines, Mode-2 or even Mode-3 can be utilized.

### Mode-2 Inspection

FIG. 4 illustrates a non-limiting embodiment of a Mode-2 module 400 of the integrated inspection system of FIG. 2a. In the embodiment, Mode-2 inspection module includes the Mode-2 BF illumination unit 226 and Mode-2 collimator 254 of the lens module 250, beam splitters 244 and 246 of the beam splitter assembly module 250, and the image capture module 280 (telecentric lens 284 and image capture sensor 282). Components of the integrated inspection system not used in Mode-2 inspection or which illumination from the Mode-2 BF illumination has little interaction with are not shown to simplify the discussion.

When Mode-2 is in operation, Mode-1 BF and DF illumination units 222 and 228, as well as Mode-3 illumination unit 226, are not operational. In one non-limiting embodiment, the Mode-2 illumination unit 224 includes a Mode-2 BF illuminator. The Mode-2 BF illuminator may be a flash lamp or an LED. Other types of BF illuminators may also be useful. Similar to the Mode-1 module, the Mode-2 BF illuminator is configurable to generate BF illumination having a broadband wavelength bandwidth of 380-700 nm. For example, the wavelength of the Mode-2 BF illumination is less than the wavelength of IR illumination. The Mode-2 BF illuminator, when operating, may be controlled to generate the BF illumination in a continuous mode or in a pulse mode based on inspection requirements. In addition, the intensity may also be controlled based on inspection requirements.

In one non-limiting embodiment, the Mode-2 module is configured to enhance the detection of submicron irregularities, such as submicron cracks or grinding lines, by employing a collimated broadband BF illumination system. The BF illumination from illuminator 226 is collimated by collimator 256, positioned between the Mode-2 BF illuminator and beam splitter 244, to ensure parallelism of light rays. This configuration enables the illumination to travel parallel and perpendicularly toward the surface of the die 100, via beam splitters 244 and 246.

The collimated BF illumination is reflected perpendicularly toward the surface of the die by beam splitter 246. The illumination incident on the back surface of the die is then reflected back through beam splitter 246 toward the image capture module 280. The telecentric lens 284 ensures a constant magnification of the die under inspection across the field of view, facilitating dimensional inspections as required.

Although the primary focus of Mode-2 is the detection of submicron irregularities, micron-sized cracks or greater will also be clearly visible in images captured during Mode-2 operation.

When Mode-2 is in operation, the Mode-2 BF illuminator of the Mode-2 illumination unit 224 will be activated. Broadband collimated illumination will travel toward beam splitter 244. Illumination passing through the beam splitter will be absorbed by light-absorbent material 245 to prevent further internal reflection and hence reduce optical noise in the images captured. The illumination that is reflected by beam splitter 244 will travel toward beam splitter 246 which will in turn reflect the illumination toward the surface of the die 100.

As the Mode-2 BF illuminator 224 is configured to emit broadband illumination with a specified wavelength bandwidth of 380-700 nm, any such illumination passing through beam splitter 246 toward the reference mirror, 262 will pass through the reference mirror and be absorbed by the light absorbent material 264. As explained in relation to the operations of Mode-1, the reference mirror is a dichroic mirror with a special coating that will reflect illumination with a wavelength higher than 750 nm while letting through all illumination with wavelengths 380-700 nm. The reference mirror is not a component of the Mode-2 module but its interaction with illuminations from the illumination units 222, 228 and 226 has to be explained. Allowing such illuminations to pass through and be absorbed by the light-absorbent material 264 prevents the reflection of the illuminations at reference mirror 262 that would otherwise occur. This is important because if such illumination from illuminator 226 is reflected to the beam splitter 246, it would interfere with light reflected from the die traveling toward the image capture module which undermines the ability of the Mode-2 module to produce sharp images necessary for defect detection including detection of submicron irregularities.

BF collimated broadband illumination reflected by beam splitter 246 will travel perpendicularly toward the surface of the die. The illumination incident on the back die surface is reflected back through the beam splitter 246 toward the image capture module 280. The telecentric lens 284 ensures that the magnification of the die/s under inspection does not change across the field of view. This facilitates dimensional inspections as required. Although a focus for Mode-2 is the detection of submicron irregularities, micron-size cracks will also be clearly shown in images captured under Mode-2.

The Mode-2 module, depending on its configuration of objective lenses and sensors which include some low-cost configurations shown in Table A, may be able to detect and resolve defects up to 1-5 microns in size. Resolving defects for the purpose of this disclosure means the ability of the inspection module to provide true dimensions of the defects through images obtained. Based on the low-cost configurations, when the Mode-2 module may have a defect resolution of up to only 4.6 μm, it will be able still to detect the presence of submicron irregularities such as submicron cracks or grindings lines. When such submicron cracks or grinding lines (e.g., 0.25 μm) are smaller than the defect resolution threshold of the inspection system, it will show up as the size of the pixel in the image capture, i.e., 4.6 μm which is not the true size of the irregularity (crack or grinding line) detected.

As explained earlier, the use of collimated illumination and telecentric lenses enhances the ability of Mode-2 module to detect such irregularities even if it cannot resolve its true size. For example, in the absence of any irregularities, such as cracks, contaminants, or grinding lines, the collimated illumination incident on the exposed back die surface will be regularly reflected to the image capture module 280. However, if there are submicron cracks or grinding lines, the parallel rays hitting the rough edges inner surface of the submicron cracks or rough surfaces of fine grinding lines will be reflected away from the image capture module and show up as pixel-sized lines or dots in the image captured. This should be contrasted with an image if diffused illumination is used as in Mode-1. In such a case, illumination from multiple directions incident on the cracks may enter the image capture module, reducing the contrast of irregularities present in the image. Although Mode-2 can detect submicron-sized irregularities, it cannot resolve whether they are cracks, griding lines, or contaminants.

The inability to discern between actual defects (cracks) and non-defects (grinding lines or contaminates) can result in excessive false positives. For example, packages that are not defective due to grinding lines may be categorized as defective.

The problem, however, is that Mode-2 inspection is unable to discern whether the submicron irregularities are associated with grinding lines, particulates, or cracks. Submicron cracks may be considered defects while grinding lines and particulates are not. Mode-3 inspection, on the other hand, can detect and discern the difference between a submicron crack or grinding lines.

### Mode-3 Inspection as Part of the Integrated Inspection System

Mode-3 inspection uses a Michelson setup adapted (adapted Michelson setup) to produce fringe patterns from illumination reflected from the surface being inspected (in this case die surface) when such illumination interferes with the illumination reflected by the reference mirror as it enters the image capture module. In non-limiting embodiments of Mode-3, instead of a conventional Michelson setup for precise measurements, the present adapted Michelson setup is used to produce fringe patterns which are then analyzed to detect and discern between submicron cracks and grinding lines. For example, the system includes a detection module employed to analyze the fringe patterns to discern between submicron cracks and grinding lines. The detection module may also be referred to as an analyzer module.

There are many advantages in using this approach as will be discussed later.

FIG. 5 shows one non-limiting embodiment of a Mode-3 inspection module 500. The Mode-3 inspection module includes a Mode-3 illumination unit 224, Mode-3 collimator 254, Mode-3 illumination or beam shaper lens assembly 255, beam splitters 242, 244 and 246, the reference module 260, and image capture module 280. Beam splitter 244 is not required in the operation of the Mode-3 inspection module. It is shown in FIG. 5 because it is part of the integrated inspection system.

As stated, the Mode-3 inspection module employs the use of the Mode-3 illumination unit 226 with a Mode-3 illuminator. The Mode-3 illuminator may be a laser diode coupled with a configurable wavelength filter to provide IR illumination. In one non-limiting embodiment, the filter be configured to generate IR illumination having a wavelength from 750-100 nm or from 750-950 nm. In one non-limiting embodiment, the filter is configured to generate IR illumination having a wavelength of 785 nm. For interference fringe patterns to form at image capture 282, the illuminator used should have a long coherence length, i.e., able to maintain a constant phase and amplitude over time and space; at least up to where the image capture plane of the image sensor unit 282 where the fringes are formed. The illumination reflected by the die surface and that of the reference mirror must originate from one source. The use of a laser diode for the Mode-3 illuminator meets this requirement.

In this embodiment, the Mode-3 illuminator is an IR illuminator configurable to generate IR illumination having a wavelength anywhere between about 750-1000 nm or 750-950 nm. Other IR wavelengths may also be useful. There is an upper limit to the wavelength used for the IR illuminator in this embodiment. Any wavelength that would make silicon transparent to the IR illumination cannot be used. That upper limit would be around 1100 nm. For this embodiment, the preferred bandwidth for IR illumination is set at 750-950 nm. The upper and lower limitations of the preferred bandwidth for IR illumination provide a suitable buffer against going near wavelength where the silicon begins to be transparent to the illumination; as well as staying clear from the broadband wavelength bandwidth used in Mode-1 and Mode-2 modules. In one non-limiting embodiment, the wavelength of the IR illuminator is 785 nm.

The deployment of the Michelson setup in the integrated inspection system for silicon die or wafer crack inspection is enabled by two key adaptations: (a) wavelength segregation and in one non-limiting embodiment, beam splitter 242 is configured as a dichroic mirror with a special coating that enables it to reflect substantially all IR illumination from IR illuminator 226 (with a wavelength above 750 nm but below 1000 nm or 950 nm) when Mode-3 is in operation (Mode-3 illuminator) and while allowing BF illumination from the Mode-1 illuminator having a wavelength bandwidth of 380-700 nm to pass through when Mode-1 is in operation. With the coating, almost 100% of IR radiation from the Mode-3 IR illuminator is reflected by beam splitter 242 to the second beam splitter 244 when Mode-3 is in operation. Any IR illumination that manages to pass through beam splitter 242 will be absorbed by light-absorbent materials 243.

Beam splitters 244 and 246 are 50/50 beam splitters, i.e., 50% of illumination is transmitted through and 50% is reflected. In particular: (a) the deliberate limitation of the IR illuminator's wavelength to any one wavelength within a band (750-1000 nm or 750-950 nm) in Mode-3 and its segregation from the wavelength bands used in Modes 1 and 2 (380-700 nm) allows for the deployment of a requisite component in Michelson setup-reference mirror (adapted and dichroic); (b) the setting of the upper limit allows the Michelson setup to be deployed toward silicon die inspection such that any wavelength higher or nearer to 1050-1100 nm will make silicon transparent to the IR illumination and make fringe pattern production impossible; and (c) dichroic reference mirror 262, which selectively transmits and reflects specific wavelengths, allows for the integration of the Michelson setup into an integrated inspection system while maintaining the functionality of 3 modes of inspection (Mode-1, Mode-2 and Mode-3); (d) the reference mirror 262, unlike conventional interferometry set used for measurements, is fixed and static during operations. It does not move.

These adaptations enable the effective deployment of the Michelson setup in an integrated inspection system, facilitating the integration of the 3 inspection modules (which share common components) for a wide-ranging detection capability including the use of high-quality fringe pattern generation for submicron crack detection and differentiation from grinding lines.

In one non-limiting embodiment where a laser diode is used to generate IR illumination for Mode-3 inspection, the generated IR illumination has an aspherical wavefront. Such an aspherical wavefront does not produce good-quality fringe patterns. The IR illumination from illuminator 226 is first collimated with the Mode-3 collimator 255 to produce a collimated IR illumination. In one non-limiting embodiment, the aspherical-shaped collimated IR illumination is then shaped and transformed to a collimated IR illumination with a planar wavefront by the Mode-3 illumination shaper lens assembly 256. A planar wavefront creates clear, high-contrast interference fringes, making it easier to analyze surface topography, defects, or other features. The planar wavefront also minimizes aberrations, which can distort fringe patterns and lead to inaccurate results when the images are analyzed.

In one non-limiting embodiment, the reference module is disposed in the illumination path of beam splitters 242, 244, and 246. The reference mirror 262 in reference module 260 is configured (using special coating) to pass illuminations from Mode-1 and Mode-2 with wavelength bandwidth of between 380-700 nm so that they will be absorbed by the light absorbent material 264, when Mode-1 or Mode-2 is in operation. However, when Mode-3 is in operation, IR illumination with of any one wavelength between 780 to 1000 nm passing through beam splitter 246 onwards to the reference mirror will be reflected by the reference mirror 262 back to the beam splitter 246 where it will coincide with and interfere with illumination reflected from the die 100 when reflected toward the image capture module 280. The segregation of operating wavelength bandwidth for Mode-3 on the one hand and that for Mode-1 and Mode-2 allow their respective apparatus to be implemented as an integrated or single inspection system.

For Mode-3 inspection to work, the length of the illumination path A₁ between the center of beam splitter 246 and the center of the reference mirror 262 and the illumination path A₂ from the center of beam splitter 246 to the surface of the die 100 are configured to have the illuminations reflected from the reference mirror and from the die surface to interfere constructively as they travel toward the image capture module. Constructive interference of the reflected illuminations from the reference mirror and the die surface produces regular fringe patterns from the die surface. In one non-limiting embodiment, A₁ is equal to A₂ to effect constructive interference to produce fringe patterns from illumination reflected from the surface being inspected. Other configurations of A₁ and A₂ in which the reflected illuminations from the reference mirror and the die surface constructively interfere may also be useful.

FIG. 2b shows another possible non-limiting embodiment where the reference module 260 is folded upwards using reference reflector 265 to reduce the footprint of the overall inspection system 200. The reference reflector is configured so that the optical path length of A₁ is the same as that of A₂ to effect interferometry in Mode-3. In this embodiment, A₁ would be the aggregate optical path length from the center of beam splitter 246 to the center of reference reflector 265 and from the reference reflector 265 to the center of the reference mirror 262. Other configurations of A₁ and A₂ in which reflected illuminations form the reference mirror and the die surface constructively interfere may also be useful.

While we have described Mode-3 module as part of an integrated inspection system which also includes Mode-1 and Mode-2 modules, it is possible to implement the Mode-3 module as an independent inspection system. Where Mode-3 is deployed independently as a standalone inspection system, other wavelengths for illumination 224 may also be useful so long as they have a long coherence length and are not limited to IR illumination bandwidth. Any wavelength between 380-1000 nm or 380-950 nm can be used. In such a standalone embodiment, the reference mirror 262 will not require a special coating to accommodate the operating wavelength of illumination used in Mode-1 and Mode-2 since it is a standalone system. For example, there are no Mode-1 and Mode-2 illuminations which need to be considered.

In this section, the operations of the Mode-3 are explained. This explanation applies to whether Mode-3 is used as part of an integrated inspection system or as an independent (standalone) inspection system.

When Mode-3 is in operation, Mode-1 illuminators (BF and DF illuminators of Mode-1 illumination units 222 and 228 of FIG. 2a) as well as Mode-2 illuminator (BF illuminator of Mode-2 illumination unit 226 of FIG. 2a) are not in operation. When Mode-3 is activated, IR illumination emanating from the IR illuminator of the Mode-3 illumination unit 226 is first collimated by Mode-3 collimator 255 and then shaped to a planar wavefront by Mode-3 illumination shaper lens assembly 256. The Mode-3 collimator and Mode-3 lens assembly are part of, for example, the lens module 250. Almost 100% of the IR illumination traveling to the dichroic beam splitter 242 is then reflected toward beam splitter 244 and then 246. Any illumination passing through beam splitter 242 downwards and any illumination reflected downwards at beam splitter 244 will be absorbed by light-absorbent materials 243 and 245 respectively.

When the IR illumination hits beam splitter 246, 50% will pass through toward the reference mirror 262 and the other half of the IR illumination will be reflected downwards toward the inactive surface of the die being inspected. As explained the dichroic reference mirror will reflect IR illumination with wavelength above 750 nm (while allowing illumination with wavelength bandwidth 380-700 nm to pass through and be absorbed by light absorbent material 264) back to the beam splitter. At the same time, the collimated IR illumination with a planar wavefront will incident the surface of the die perpendicularly and be reflected back to the beam splitter 246 where it will pass through (toward the image capture module) and interfere with illumination reflected back from the reference mirror 262, also reflected by the beam splitter to the image capture module 280.

The interference between illumination reflected from the reference mirror 262 and that reflected off the surface die results in fringe patterns being formed over the image of the surface of the die being inspected. Mode-3 uses an inherent physical characteristic of cracks (micron-sized or submicron-sized), not typical of grinding lines, to detect and distinguish submicron cracks from grinding lines. It is characteristic of cracks that the two adjacent surfaces to and along the ridges of the cracks are of different height and more often than not also at different planarity to one another. Grinding lines and minute contaminants, on the other hand, do not share this characteristic. More often than not, the two adjacent surfaces to the ridges of grinding lines share substantially the same planarity. FIG. 1c illustrates the difference in planarity and also in height, h₁ and h₂, of the two adjacent surfaces to the crack. The height difference of two adjacent surfaces along the submicron cracks are typically in the order of 0.2 μm. The planarity of the two adjacent surfaces to the crack would also be different. Mode-3 using wavelength 785 nm can detect height differences/planarity greater than 0.005 μm. Any changes in height surfaces or planarity greater than 0.005 μm would produce a change in fringe pattern. Where the die surface has no cracks, the image of the die will show one continuous fringe pattern over the image of the die.

Where Mode-2 image indicates possible submicron cracks or grinding lines in some surface region of a die but is not able to distinguish between them, Mode-3 can be used to confirm the presence of the submicron crack (e.g., down to 0.2-0.25 um) or that they are just minor surface irregularities (grinding lines). This can be done by comparing the region in Mode-2 image where a possible defect is present, with the same region in Mode-3 image. If Mode-3 image shows changes in the fringe pattern in the same region, the submicron crack is then confirmed.

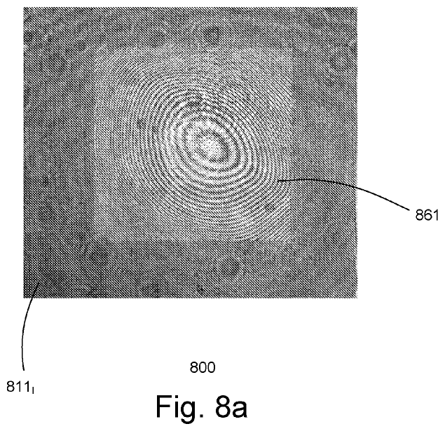

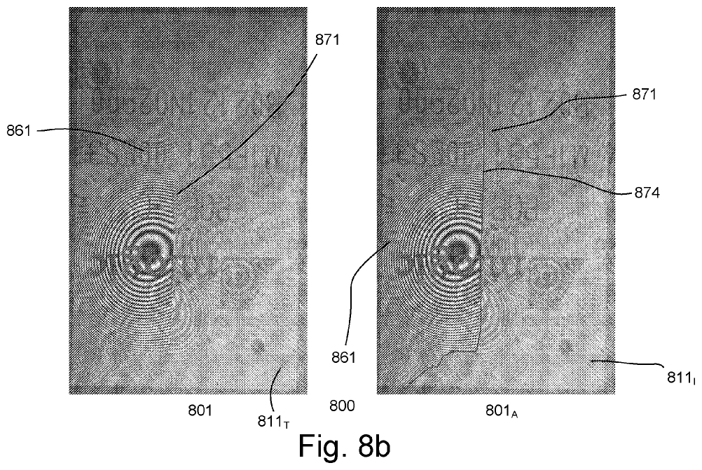

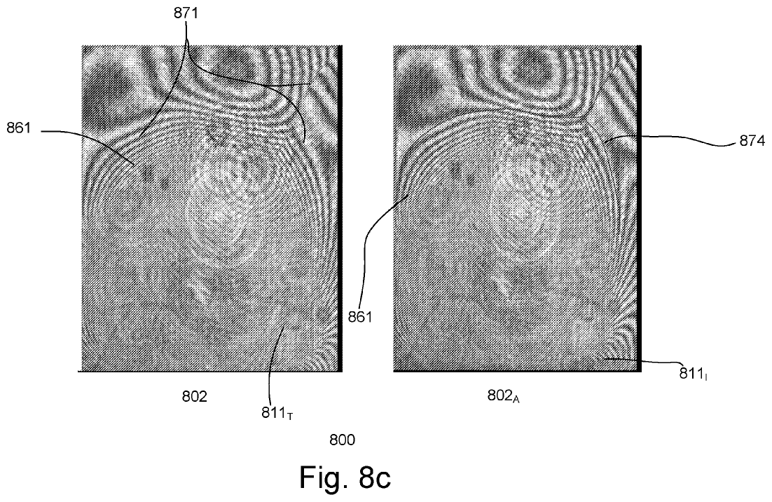

Image 800 in FIG. 8a shows an exemplary image from Mode-3 inspection of the inactive surface 811₁ of a die. There is only one continuous fringe pattern 861, indicating that no abrupt change in the planarity of the die surface inspected. This therefore indicates that no submicron cracks are present.

Where there is a crack on the die surface, the continuous fringe pattern would be broken, and another fringe pattern would be formed from where the crack is present. FIG. 8b shows an exemplary image of another die having its inactive surface 811₁ being inspected. As shown, the inactive die surface has an extended crack. Image 801 shows that the concentric ring fringe pattern 861 is broken, and immediately followed by another fringe pattern 871 in another direction. Analyzing and delineating the border/location where the changes in fringe patterns occur, the Mode-3 inspection module is able to exactly delineate the location of the crack/s on the die. This delineation is achieved through precise inspection algorithms that identify the exact border where the fringe pattern changes occur, which corresponds to the crack's location. The highlighted red line 874 in image 801A in FIG. 8b delineates and corresponds to where the crack is and where it extends to on the die. Utilizing the known magnification and die dimensions, the inspection system then uses algorithms or mathematical formulas to calculate and determine the crack's location, length, and orientation on the die with high precision.

FIG. 8c shows another exemplary image of another die having its inactive die surface 811₁ being inspected. The inactive die surface has an extended crack. Image 802 shows that the concentric ring fringe patterns 861 is broken, and immediately followed by another fringe patterns 871 in different directions. Analyzing and delineating the border/location where the changes in fringe patterns occur, the Mode-3 inspection module is able to exactly delineate the location of the crack/s on the die. This delineation is achieved through precise inspection algorithms that identify the exact border where the fringe pattern changes occur, corresponding to the crack's location. As illustrated, the crack extends in different directions, as indicated by the highlighted red line 874 in image 802A in FIG. 8b delineates and corresponds to where the crack is and where it extends to on the die. Utilizing the known magnification and die dimensions, the inspection system then uses algorithms or mathematical formulas to calculate and determine the crack's location, length, and orientation on the die with high precision.

It is noted that the images of FIGS. 8a-8c are captured using IR illumination with an aspherical wavefront. For example, the IR illumination was not transformed by a Mode-3 illumination shaper lens assembly. As such, the fringe patterns are spiral fringe patterns. On the other hand, in the case where IR illumination with a planar wavefront is used, the fringe pattern would be regular parallel fringes.

Even if the die being inspected is sitting off planarity, Mode-3 will still be able to distinguish between grinding lines and cracks. The fringe pattern for a die with grinding lines sitting slightly off planarity will still be continuous albeit with more compressed fringe rings on one side. On the other hand, cracks, even for a die that is seated slightly off planar during inspection will produce changes in different fringe patterns on the die image due to the differences in planarity and height of the adjacent surfaces along the crack.

In fact, with more training, the algorithms used to analyze the fringe patterns in the images captured to detect possible internal cracks often portended by a bulge on die surface. The planarity of the wavefront of the illumination from the Mode-3 IR illuminator will enhance this capability. Illumination with a planar wavefront would produce fine fringe patterns with more even pitches on the die image. Any awkward bulge on the die surface caused by an internal crack will still produce changes to the planarity and height of surfaces near it, and in turn, produce changes in fringe patterns.

Table A shows some possible configurations of lenses and images that may be deployed for the inspection system and the different field of views that may be utilized as a result. What is significant is that whatever the defect resolution that results from such configurations for Mode-1 and Mode-2 modules, Mode-3 inspection module's ability and sensitivity to detect submicron cracks is determined principally by the wavelength used in the Mode-3 illuminator of the Mode-3 illumination unit 226.

### Sensitivity of Mode-3 System

The sensitivity of Mode-3 module to surface topology is determined by the mathematical formulation (Sensitivity(S)) below:

S=(δφ_min)/(4π*(δh/λ))=(δφ_min*λ)/(4π*δh) (Equation 1)

Where:
S=Sensitivity (in units of surface height, e.g., meters, nanometers);
δφ_min=Minimum detectable phase shift (in radians);
δh=Change in surface height (in meters); and
λ=Wavelength of the light source (in meters).

Assuming a minimum detectable phase shift (δφ_min) 0.01 radians and given the wavelength of the Mode-3 illuminator is 785 nm, Mode-3 will be able to detect surface height changes to 0.005 μm. Similarly, if a wavelength of 440 nm is used, the sensitivity improves to 0.0035 μm. However, the sensitivity of the Mode-3 interferometer system can be affected by the magnification of the objective lens used. At 1× magnification, the sensitivity of a 440 nm system would decrease to 0.035 μm. With 5× magnification, it can increase to 0.00175 μm.

Rearranging Equation 1:

S=(0.01*785×10\hat{ }−9 m)/(4π*S×10\hat{ }−9 m)

Simplifying:

S=0.0625/(4π*S)

S≈5.0 nm

Equation 1 provides a way to understand how sensitive Mode-3 inspection module is to topological surface changes. As explained, in non-limiting embodiments, interferometry is not used to measure any height differences. The calculation of sensitivity is NOT for the present purposes to determine how accurate any measurement can be of any planarity difference, but merely to determine how small the change in planarity needs to be to trigger changes in fringe pattern from the surface being inspected.

The interferometry in Mode-3 is used instead to generate fringe patterns which are then analyzed by algorithms to detect the presence of submicron cracks. The approach to use fringe patterns as a basis for drawing inferences as to whether a defect is a submicron crack, or a grinding line is more forgiving in terms of sensitivity of setup and operating environment. For example, even if the setup for A₁ and A₂ is not equal or not precisely equal, a constant phase difference between the illumination from the reference mirror 262 and die surface 100 to the image capture module would result. This would not matter in relation to the production of regular fringe patterns. Regular fringe patterns can still be produced from the die surface, so long as fine relative adjustment of the distance of reference mirror to beam splitter 246 ensures that the two waves (with a constant phase difference) interfere constructively, i.e. troughs to troughs and peaks to peaks. Fine adjustments to the distance between the reference mirror ensures constructive interference.

This allowance, through the use of fringe patterns, means that the reference mirror can be placed more compactly in the whole setup if required so long as a constant phase difference is maintained and interference is ensured between the illumination reflected from the reference mirror and the surface of the die. Thus, where there is constructive interference, then when there is no defect on the die surface, this constant phase difference (resulting from set-up error) would still result in only one continuous fringe pattern forming in the image of the die. On the other hand, if there is a crack, absolute phase changes arise from changes in planarity along both adjacent surfaces of the crack. Such absolute phase differences relative to the constant phase difference on surfaces of surfaces that are planar and without cracks will generate different fringe patterns on the surface of the die image capture, indicating the presence of a crack.

In one non-limiting embodiment, Mode-3 captures and analyzes the captured images of the fringe patterns over the surface of the die. For example, the fringe patterns from the interference of light reflected from the surface with that from the reference mirror are analyzed. If an image from Mode-2 inspection indicates a possible submicron-sized irregularity at a location of the die surface, the image from Mode-3 is used to confirm whether the submicron-sized irregularity is a crack and not a grinding line. For example, the same location of the die surface in the Mode-3 image is analyzed. If there are changes in the fringe pattern in the same location of the two images, an inference can be drawn that the surface irregularity is a crack. On the other hand, if there are no changes in the fringe pattern in the same location of the two images, then an inference is drawn that the surface irregularity is not a crack (e.g., a grinding line or a contaminate). Mode-3 therefore is used to distinguish between a crack and a non-crack (e.g., a grinding line or a contaminate) based on a change in the fringe pattern. Furthermore, the location and profile of the crack can also be analyzed from the fringe pattern imaged and inferred by correlating the localized fringe pattern changes captured in the image against the surface of the die.

### Inspection of Devices in Trays

When inspecting packaged die, these dies would mostly sit in a pocket of a tray at the planar platform 210 with the surface requiring inspection facing up toward the image capture module. The die may be further held in place aided by vacuum suction facilitated by small holes in the tray pocket. More than one die on the tray may be presented for inspection at the planar platform so long as they are within the FOV of the inspection system.

During operation in Mode-1, Mode-2 and Mode-3 illuminators are not operational. The inspection sequence will be optimized based on the FOV of the inspection system and the tray dimensions, ensuring that all dies on the tray are inspected efficiently. The system will determine the optimal number of dies to inspect in each image capture, whether it's one die or multiple dies. Additionally, depending on the defect inspection requirements, one or multiple image captures may be performed for each batch of at least one die inspected. For example, an inspection capture of a batch, which may include one or more dies, may include one or more image captures, depending on the defect inspection requirements. After an inspection capture, the platform translates or moves to inspect the next batch of the tray.

When Mode-1 inspection is completed for each batch (all dies) of the tray, Mode-2 inspection commences for the dies of the tray, batch by batch, similar as Mode-1 inspection. During Mode-2 inspection, Mode-1 and Mode-3 illuminators are not operational. When Mode-2 inspection is completed, Mode-3 inspection starts. During Mode-3 inspection, Mode-2 and Mode-1 illuminators are not operational. When Mode-3 inspection is completed, this completes the inspection of the dies of the tray. The inspected tray of dies may be removed from the platform and then an uninspected tray of dies is placed thereon. The uninspected tray of dies goes through the inspection cycles as described. Other configurations for inspecting dies may also be useful.

### Wafer Mode Inspection

The system, integrated or standalone, can also be used to inspect a wafer (wafer mode). When inspecting the surface of a plain wafer or surface of a layered dielectric wafer, the wafer chuck/platform (e.g., planar platform 210 of FIGS. 2a-2b) holding the wafer will be configured to index-move the wafer such that taking into account the FOV of the inspection system and the need for overlap in the images captured at its edges, to enable stitching of all adjacent images so that an image of the complete wafer for inspection can be produced. The encoder of information on the movement of the wafer chuck for each image capture is recorded. Given that the orientation, dimension of the wafer, and its precise position on the wafer chuck are known, the location of each image can be correlated to the wafer surface. Furthermore, the location and the type of any defect detected can be calculated and stored by the inspection system.

MEMS and other devices with shiny surfaces are usually inspected as part of a wafer. Their inspection will be handled in, for example, the wafer mode. Utilizing the same principles, defects detected in images of dies captured during wafer inspection can be correlated to each die on the wafer. As the inspection system scans the wafer, starting from the first die in the first row/column, the location of each die is tracked and recorded, taking into account the field of view (FOV) of the system and the overlap required for image stitching. By correlating the die's location on the wafer with the corresponding image, defects detected within each image can be accurately attributed to their respective dies. Furthermore, by utilizing the encoder data and wafer mapping information, the inspection system can precisely determine the position of each die on the wafer, enabling accurate correlation of defects to individual dies, and facilitating comprehensive defect analysis and reporting.

In wafer mode inspection, each of the three Modes (Mode-1, Mode-2, and Mode-3) will sequentially complete their image capture of all the dies on the wafer, with each Mode capturing images of all dies before the next Mode starts. This results in three complete scans of the dies on the wafer. During each scan, the processing of images captured and stitching of overlapping images occurs in real-time, utilizing the encoder information to ensure accurate die-to-die registration. The inspection system stores the results of each scan, which include:
Encoder information (wafer position, die location, and image overlap data);
Defect types and locations (classified and stored for each die);
Image data (stitched and processed images of each die); and
Wafer map data (updated with defect information and die registration).
   After completing all three scans, the inspection system can combine the results to provide a comprehensive analysis of defects across all dies on the wafer, enabling accurate defect classification, binning, and reporting.

The integrated inspection system performs comprehensive defect detection and classification across three modes, utilizing buffer memory to efficiently handle and store image data. For example:
Mode-1-Detects and classifies defects such as contaminants, scratches, divots, and pits, storing defect information in buffer memory;
Mode-2-Detects micron cracks, identifies potential defects (submicron cracks and grinding lines), and links them as Defect Regions of Interest (DROI) in buffer memory; and
Mode-3-Retrieves DROI data, captures high-resolution fringe pattern images, and analyzes fringe patterns to distinguish between actual defects (micron and submicron cracks) and non-defects (grinding lines), finalizing defect classification.

In the tray-based inspection, the system completes all three modes sequentially for each batch of dies, enabling real-time defect analysis and classification. In wafer mode inspection, the system:
retrieves Mode-2 DROI data for one or more dies within each frame captured during Mode-3;
stores captured data in buffer memory for offline processing;
performs offline processing of stored data to detect changes and confirm cracks, including submicron cracks;
stores all results, including images, in permanent memory for future review; and
Completes all the above steps before inspecting the next batch of dies on the wafer.

Depending on the manufacturer, dies with cracks may be classified as defects while those with grinding lines and contaminates are not. The ability to accurately detect whether a submicron-sized irregularity is a crack or a grinding line (or contaminants) reduces false alarms.

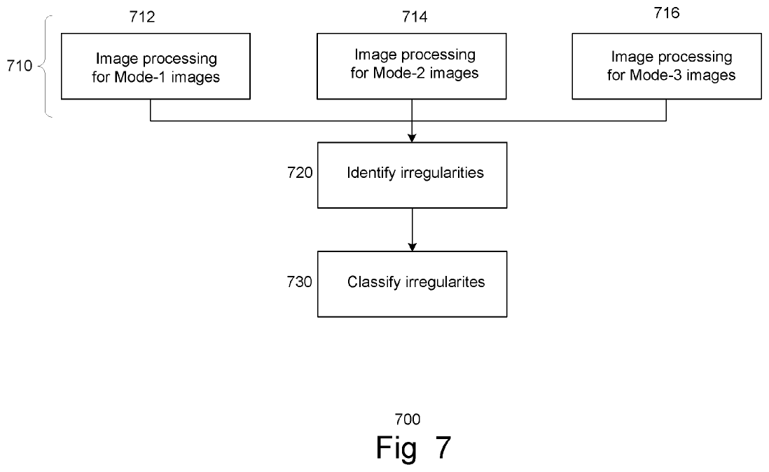

FIG. 7 shows a non-limiting embodiment of a process flow 700 for detecting defects (cracks versus non-cracks) from images captured by the different inspection modes and by the system. At 710, the system performs image processing of images captured in the different inspection modes. As shown, Mode-1 images are processed at 712, Mode-2 images are processed at 714 and Mode-3 images are processed at 716.

In one non-limiting embodiment, the processing unit of the system analyzes the images using image processing techniques. For example, an AI analyzer containing an inspection algorithm may be used to identify defects of interest. The AI analyzer may be trained with a progression of images showing different surface irregularities, such as cracks, grinding lines, and surface particulates to develop a comprehensive understanding thereof.

For Mode-1 inspection, it is configured to capture micron-sized or larger surface irregularities, such as cracks, grinding lines, and particulates, on the back die surface. The images are captured using the first BF illumination unit and the fourth DF illumination unit. The images are processed using image processing techniques.

For Mode-2 inspection, it is configured to capture micron-sized and submicron-sized surface irregularities. However, Mode-2 cannot resolve whether the surface irregularities are cracks or non-cracks (grinding lines and contaminates). The images are captured using the second BF illumination unit generating collimated BF illumination. The images are processed using image processing techniques.

Mode-3 is configured to capture fringe patterns of submicron-sized irregularities on the back surface. For example, Mode-3 captures images using the third illumination unit. In one non-limiting embodiment, Mode-3 employs interference using collimated IR illumination to capture fringe patterns on the back die surface. Mode-3 images are compared with Mode-2 images to determine if there are changes in the fringe patterns at locations with submicron-sized irregularities.

The AI analyzer determines from the images if there are any irregularities at 720. For example, the irregularities are identified from the images. The irregularities are classified at 730. For example, the analyzer categorizes the irregularities. In one non-limiting embodiment, the irregularities are classified as cracks or non-cracks. For example, crack lines are classified as cracks while grinding lines and contaminates are classified as non-cracks. Depending on the manufacturer, cracks may be determined as defects while non-cracks are non-defects. Other manufacturers may perform additional tests to determine which dies with cracks are still functional while others are not.

The sequences of the flow can be interchangeable or performed simultaneously with each other to reduce the turnaround time for the analysis in accordance with the defects mode or modes in operation at the inspection time.

This disclosure illustrates a novel system and method to detect visible and non-visible defects on the back die surface of a semiconductor package. The system and method will enable the detection of a full range of micro and macro-sized surface defects down to submicron cracks (typically of less than 0.5 μm) with minimum false alarms in a single pass and at production speeds of at least 10,000 units per hour (UPH).

Preferably, and in non-limiting embodiments, the workpiece may include at least one semiconductor die; a semiconductor wafer with unsingulated dies; a blank or plain wafer; a wafer with a dielectric layer; and the surface of the workpiece inspected depends on which surface is required for inspection.

Preferably, and in non-limiting embodiments, the semiconductor die may be a packaged die with an exposed back surface or MEMS, photonic devices or other devices with smooth shiny surfaces requiring inspection.

The present disclosure may be embodied in other specific forms without departing from the spirit or essential characteristics thereof. The foregoing embodiments, therefore, are to be considered in all respects illustrative rather than limiting the disclosure described herein. The scope of the disclosure is thus indicated by the appended claims, rather than by the foregoing description, and all changes that come within the meaning and range of equivalency of the claims are intended to be embraced therein.

1-34. (canceled)

35. An inspection system with an adapted Michelson setup for detecting cracks on a surface of a workpiece, comprising:
an illumination module configured to generate fringe patterns in an image of the surface of the workpiece illuminated, wherein the illumination module includes an illumination source, the illumination source generates the illumination;
an optical module comprising an illumination collimator to collimate the illumination from the illumination source;
an image capture module configured to capture an image of the fringe patterns; and a detection module configured to analyze and detect changes to the fringe patterns
caused by height and planarity differences in the surface along and adjacent to a crack to indicate the presence of a crack.

36. The system of claim 35, wherein the detection module is further configured to determine a location and an extent of the crack, if present, by delineating the border between fringe pattern changes in the image of the workpiece.

37. The system of claim 35, wherein the adapted Michelson setup comprises:
a reference module including a reference mirror having high reflectivity and minimal aberrations;
a beam splitter assembly module comprising a primary beam splitter, wherein the primary beam splitter assembly is configured to direct the illumination into first and second illumination paths, wherein
the first illumination path is towards the reference mirror of the reference module,
the second illumination path is towards the surface of the workpiece to be inspected with minimal illumination deviation and distortion, and
wherein the surface of the workpiece and the reference mirror are configured with a relative distance between a center of reference mirror to a center of the primary beam splitter and the distance of the surface of the workpiece to the primary beam splitter such that reflected illuminations from the reference mirror and the surface of the workpiece maintains a constant phase difference and interfere constructively.

38. The system of claim 37 wherein the beam splitter assembly module comprises:
an illumination beam splitter configured to receive illumination from the illumination module;
a primary beam splitter configured to receive the illumination from the illumination beam splitter and direct the received illumination from the illumination beam splitter to the first and second illumination paths.

39. The system of claim 35 wherein the illumination module of the adapted Michelson setup comprises an illumination source configured to generate illumination, wherein the illumination source is configured to emit illumination with a long coherent length having a wavelength within a range of about 380-950 nm, which is optimized for inspecting a silicon-based workpiece without inducing transparency.

40. The system of claim 35 wherein the optical module further comprises an illumination shaper lens assembly configured to transform the collimated illumination to a collimated illumination with a planar wavefront (transformed collimated illumination).

41. The system of claim 35 wherein the image capture module comprises:
an image sensor with a predetermined resolution, sensitivity, and dynamic range; and
a telecentric lens configured to provide a large field of view (FOV) and distortion-free imaging with minimal vignetting for inspecting the workpiece

42. The system of claim 35 wherein the illumination module comprises a LED diode coupled to a wavelength filter configurable to select a wavelength within a range of 380 nm to 950 nm.

43. The system of claim 42, comprising a planar platform configured to position the workpiece for inspecting the surface of the workpiece, wherein positioning the workpiece comprises positioning a tray holding a plurality of workpieces which are dies, wherein all workpieces of the tray are inspected to complete inspection of the workpieces of the tray.

44. The system of claim 43, wherein a processor automatically initiates the detection module to analyze the images for presence of cracks.

45. The system of claim 43, wherein positioning the workpiece comprises positioning a wafer, wherein the inspection system scans the surface of the whole wafer to complete inspecting the surface of the whole wafer.

46. The system of claim 45 wherein a processor automatically initiates the detection module to:
stitch images to form a stitched image of the surface of the whole wafer; and analyze the stitched image to detect the presence of cracks.

47. An integrated inspection system for detecting surface irregularities on a surface of a workpiece, comprising:
a Mode-1 inspection module comprising a Mode-1 illumination unit comprising a Mode-1 BF illuminator and Mode-1 DF illuminators configured to illuminate the surface of the workpiece on a planar platform with co-axial diffused bright (BF) illumination or darkfield (DF) illuminations, respectively or a combination thereof, to detect micron-sized surface irregularities on the surface of the workpiece to obtain Mode-1 images of the surface of the workpiece, wherein the surface irregularities include contaminates, cracks and grinding lines;
a Mode-2 inspection module comprising a Mode-2 BF illumination unit configured to illuminate the surface of the workpiece on the planar platform with a Mode-2 BF illumination to obtain Mode-2 images of the surface of the workpiece, a Mode-2 collimator for collimating the Mode-2 BF illumination to produce the collimated Mode-2 illumination to illuminate directed perpendicularly to the surface of the workpiece to detect micron-sized and submicron-sized surface irregularities;
a Mode-3 inspection module comprising a Mode-3 IR illumination unit configured to illuminate the surface of the workpiece on the planar platform with Mode-3 IR illumination to produce regular fringe patterns from the surface of at least one die, a Mode-3 collimator for collimating the Mode-3 IR illumination to produce the collimated Mode-3 IR illumination to illuminate the surface of the workpiece to obtain Mode-3 images of the surface of the workpiece, wherein changes in the fringe patterns are indicative of height and planarity differences between the surface along and adjacent to a crack which are crack characteristic of a crack's presence, thereby enabling the detection of the submicron crack and differentiating submicron cracks from grinding lines that lack the crack characteristic;
a beam splitter assembly module configured to split the illuminations from the Mode-1, Mode-2, or Mode-3 inspection modules, when operating in Mode-1, Mode-2 or Mode-3 inspection modes along first and second illumination paths, and
an image capture module for capturing Mode-1 images in Mode-1 inspection mode, Mode-2 images in Mode-2 inspection mode and Mode-3 images in Mode-3 inspection mode, wherein the image capture module comprises an image sensor with a predetermined resolution, sensitivity, and dynamic range.

48. The integrated inspection system of claim 47, further comprising:
a reference module comprising a reference mirror and a reference illumination absorber, wherein
the first illumination path is directed to the reference module,
the second illumination path is directed to the surface of the workpiece with minimal illumination deviation and distortion, and
wherein the first and second illumination paths are configured such that reflected illuminations from the first and second illumination paths in Mode-3 inspection maintains a constant phase difference and interfere constructively.

49. The integrated system of claim 48 wherein:
a Mode-1 BF bandwidth of the Mode-1 BF illumination is about 380-700 nm;
a Mode-2 BF bandwidth of the Mode-2 BF illumination is about 380-700 nm; and a Mode-3 IR bandwidth of the Mode-3 IR illumination is about 750-950 nm.

50. The integrated system of claim 48, wherein the reference mirror of the reference module comprises a dichroic mirror configured to allow Mode-1 and Mode-2 illuminations to pass therethrough to the reference illumination absorber wherein the Mode-1 and Mode 2 illuminations are absorbed and to reflect Mode-3 illumination, wherein the first and second illumination paths are configured such that reflected Mode-3 illuminations from the first and second illumination paths from the reference mirror and the surface of the workpiece in Mode-3 inspection maintains a constant phase difference and their distance from the primary beam splitter is configured to enable constructive interference.

51. The integrated system of claim 48, wherein:
during Mode-1 inspection mode, only the Mode-1 illumination unit is activated while the Mode-2 and the Mode-3 illumination units are inactive;
during Mode-2 inspection mode, only the Mode-2 illumination unit is activated while the Mode-1 and the Mode-3 illumination units are inactive; and
during Mode-3 inspection mode, only the Mode-3 illumination unit is active while the Mode-1 and the Mode-2 illumination units are inactive.

52. The integrated system of claim 48, wherein the beam splitter assembly module comprises:
a Mode-1/Mode-3 beam splitter, the Mode-1/Mode-3 beam splitter comprises a dichroic mirror configured to reflect Mode-3 illumination from the Mode-3 illumination unit and to transmit Mode-1 illumination from the Mode-1 illumination unit;
a Mode-2 beam splitter, the Mode-2 beam splitter is configured as a 50/50 Mode-2 beam splitter; and
a primary beam splitter configured as a 50/50 primary beam splitter.

53. The system of claim 48, further comprising a telecentric lens configured to provide a large field of view (FOV) and distortion-free imaging with minimal vignetting for inspecting the workpiece.

54. A method for inspection a surface of a workpiece, wherein the method distinguishes between types of submicron-sized irregularities on the surface of the workpiece, the method comprising:
performing a Mode-2 inspection mode by illuminating the surface of the workpiece with Mode-2 collimated BF illumination directed perpendicularly to the surface of the workpiece to obtain a Mode-2 image of the surface of the workpiece, wherein the Mode-2 image indicates possible micron-sized or greater and submicron-sized surface irregularities, wherein the surface irregularities include contaminates, cracks and grinding lines;
performing a Mode-3 inspection mode by illuminating the surface of the workpiece with Mode-3 collimated IR illumination to produce regular fringe patterns from the surface of the workpiece and to obtain a Mode-3 image of the fringe patterns;
analyzing Mode-2 and Mode-3 images, wherein analyzing includes
identifying an area in the Mode-2 image which indicates a possible surface irregularity,
analyzing the area in the Mode-3 image to determine if there is a fringe pattern change, and if the analysis indicates that
there are fringe pattern changes in the area, then infer that the surface irregularity is a crack, and
there are no fringe pattern changes in the area, then infer that the surface irregularity is not a crack.
